(19) United States
(12) Patent Application Publication
(10) Pub. No.: US 2005/0243347 A1
(43) Pub. Date: Nov. 3, 2005

(54) Conversion of color image to monochrome image

(76) Inventor: Ikuo Hayaishi, Nagano-ken (JP)

Correspondence Address: MARTINE PENILLA & GENCARELLA, LLP, 710 LAKEWAY DRIVE, SUITE 200, SUNNYVALE, CA, 94085, US

(21) Appl. No.: 11/075,528

(22) Filed: Mar. 7, 2005

(30) Foreign Application Priority Data
Mar. 8, 2004 (JP) 2004-64066
Feb. 15, 2005 (JP) 2005-38004

(51) Int. Cl. G06F 15/00; G03F 3/08

(52) U.S. Cl. 358/1.9; 358/518

(57) ABSTRACT

A CPU 111 acquires monochromatic output image processing conditions including the RGB channel mix rate from ROM 113 using set photograph scenes. When no command for setting the photograph scene has been input, the CPU 111 analy8zes the color image data to generate monochromatic output image processing conditions including the RGB channel mix rate. The CPU 111 generates image process control data using the set monochromatic output image processing conditions, and associates the generated image processing control data with the color image data for output.

### BACKGROUND OF THE INVENTION

1. Field of the Invention

The invention relates to a technique that generates image data associated with image process-related data, and to a technique for performing an image process on image data using the associated image process-related data.

2. Description of the Related Art

Monochromatic film can be used in silver salt cameras, and filters suited to the photograph scene can be used to produce monochromatic images which are characteristic of the photograph scene.

In contrast, the CCD corresponding to film in digital still cameras has color filters, and the resulting images are therefore always color images, making it impossible to directly obtain monochromatic images. A process for conversion to monochromatic images is therefore needed in order to obtain monochromatic images from the color images obtained with digital still cameras.

However, in conventional monochromatic image conversion processes in which RGB components are uniformly converted to a certain value, it is not possible to obtain monochromatic images which are very characteristic of the photograph scene. The user must also carry out the monochromatic image conversion through trial and error to achieve proper monochromatic conversion.

### SUMMARY OF THE INVENTION

An object of the present invention, which is intended to overcome the aforementioned problems, is to allow color images to be easily converted to monochromatic images without sacrificing the characteristics of the color images.

A first aspect of the invention for solving the above problems provides a color image data generating apparatus that generates color image data. The image data generating apparatus in the first aspect of the invention comprises: color image data generating module that generates color image data; image process control data acquiring module that acquires image process control data that stipulates the image process conditions for the generated color image data, wherein the image process control data includes monochromatic output image process conditions for outputting the generated color image data in the form of monochromatic images; and color image data output module that associates and outputs the acquiring image process control data and the generated color image data.

The color graphic generating apparatus of the first aspect of the invention acquires image process control data that stipulates the image process conditions for the generated color image data and that includes monochromatic output image process conditions for outputting the generated color image data in the form of monochromatic image, and associates image process control data with the generated color image data for output. It is thus possible to generate color image data allowing color images to be easily converted to monochromatic images without sacrificing the characteristics of the color images.

In the color image data generating apparatus in the first aspect of the invention, the monochromatic output image process conditions may include RGB channel mix rate stipulating the proportion of R, G, and B components in the RGB color image data for obtaining monochromatic images from color images. In this case, it is possible to generate color image data enabling the output of monochromatic images in which the intended color areas are enhanced in the color image data that has been generated.

The color graphic generating apparatus of the first aspect of the invention may further comprise RGB channel mix rate setting module that sets the RGB channel mix rate by analyzing the color image data; and image process control data generating module that generates image process control data including the set RGB channel mix rate, wherein the image process control data acquiring module acquires the generated image process control data. In this case, it is possible to generate color image data enabling the output of monochromatic images in which the intended color areas in the photograph scene are enhanced per individual color image data.

The color graphic generating apparatus of the first aspect of the invention may further comprise storage module for storing a plurality of RGB channel mix rates according to the conditions under which the color image data is generated; RGB channel mix rate acquiring module that acquires RGB channel mix rates from the storage module according to the conditions under which the data is generated; and image process control data generating module that generates image process control data including the acquired RGB channel mix rate, wherein the image process control data acquiring module acquires the generated image process control data. In this case, it is possible to generate color image data enabling the output of monochromatic images in which specific color areas are enhanced according to the individual color image data generating conditions.

In the color image data generating apparatus in the first aspect of the invention, the monochromatic output image process conditions may further include suitable conditions for brightness, contrast, color balance, noise rejection, and sharpness in order to obtain monochromatic images from color images. In this case, the image quality of the monochromatic output images may be further improved.

A second aspect of the present invention provides an imaging device that generates color image data. The imaging device in the second aspect of the invention comprises: color image data generating module that generates color image data; image process control data acquiring module that acquires image process control data that stipulates the image process conditions for the generated color image data, wherein the image process control data includes RGB channel mix rate stipulating the proportion of R, G, and B components in the RGB color image data for obtaining monochromatic images from color images; and image data output module that associates and outputs the acquiring image process control data and the generated color image data.

The imaging device in the second aspect of the invention may acquires image process control data that stipulates the image process conditions for the generated color image data and that includes the RGB channel mix rate stipulating the proportion of R, G, and B components in the RGB color image data for obtaining monochromatic images from color images, and associates the image process control data with the generated color image data for output. It is thus possible to generate color image data allowing color images to be easily converted to monochromatic images without sacrificing the characteristics of the color images.

The imaging device in the second aspect of the invention may further comprise photograph scene setting module that sets the photograph scene when taking photographs; RGB channel mix rate setting module that sets the RGB channel mix rate using the photographic scene; and image process control data generating module that generates image process control data including the set RGB channel mix rate, wherein the image process control data acquiring module acquires the generated image process control data. In this case, it is possible to generate color image data enabling the output of monochromatic images in which the intended color areas are enhanced in the color image data that has been generated.

The imaging device in the second aspect of the invention may further comprise photograph scene setting module that sets the photograph scene when taking photographs; storage module for storing a plurality of RGB channel mix rates according to the photograph scene; RGB channel mix rate acquiring module that acquires RGB channel mix rates from the storage module according to the set photographic scene; and image process control data generating module that generates image process control data including the acquired RGB channel mix rate, wherein the image process control data acquiring module acquires the generated image process control data. In this case, it is possible to generate color image data enabling the output of monochromatic images in which specific color areas are enhanced according to the photograph scene of the individual color image data.

In the imaging device of the second aspect of the invention, the image process control data may further include suitable conditions for brightness, contrast, color balance, noise rejection, and sharpness in order to obtain monochromatic images from color images. In this case, the image quality of the monochromatic output images may be further improved.

A third aspect of the invention provides an image processing apparatus for implementing an image process on image data. The image process device in the third aspect of the invention comprises: color image data acquiring module that acquires color image data; image process control data acquiring module that acquires image process control data that is associated with the color image data and that stipulates the image process conditions for the image data, wherein the image process control data includes monochromatic output image process conditions for outputting color image data in the form of monochromatic images; and image data conversion module that converts the color image data to monochromatic image data using the acquired monochromatic output image process conditions.

The image processing apparatus in the third aspect of the invention may acquires the image process control data that is associated with the color image data and that stipulates the image process conditions for the image data, and that includes monochromatic output image process conditions for outputting color image data in the form of monochromatic images, may convert the color image data to monochromatic image data using the acquired monochromatic output image process conditions. It is thus possible to generate color image data allowing color images to be easily converted to monochromatic images without sacrificing the characteristics of the color images.

The image processing apparatus in the third aspect of the invention may further comprise image quality adjusting module that adjusts the image quality of the monochromatic image data according to the image process conditions stipulated by means of the acquiring image process control data. In this case, the image quality of the monochromatic output images may be further improved.

In the image process device of the third aspect of the invention, the monochromatic output image process conditions may include the RGB channel mix rate stipulating the proportion of R, G, and B components in the RGB color image data for obtaining monochromatic images from color images. In this case, it is possible to output monochromatic image data in which intended color areas have been enhanced in the color image data. The image processing apparatus in the third aspect of the invention may also comprise image output module for outputting images based on the image data. In this case, it is possible to output monochromatic images in which intended color areas have been enhanced in the color image data.

A fourth aspect of the invention provides an image processing apparatus for implementing an image process on image data. The image processing apparatus in the fourth aspect of the invention comprises: image data acquiring module that acquires color image data; photographic scene data acquiring module that acquires photograph scene data that is associated with the color image data and relates to the photograph scene when the image data is generated; storage module for storing a plurality of monochromatic output image process conditions correlated with photograph scenes; monochromatic output image process condition acquiring module that acquires monochromatic output image process conditions from the storage module according to the acquired photograph scene; and image data conversion module that converts the color image data to monochromatic image data using the acquired monochromatic output image process conditions.

The image processing apparatus in the fourth aspect of the invention may be realized in a variety of ways in the same manner as the image processing apparatus in the third aspect of the invention.

A fifth aspect of the invention provides a method of generating color image data associated with image process control data stipulating the image process conditions for image data. The method in the fifth aspect of the invention comprises: generating color image data; acquiring image process control data including monochromatic output image process conditions for outputting the generated color image data in the form of monochromatic images; and associating and outputting the acquiring image process control data and the generated color image data.

The method in the fifth aspect of the invention may provide the same action and effects as the color image data generating apparatus in the first aspect of the invention. The method that generates color image data in the fifth aspect of the invention may also be realized in a variety of ways in the same manner as the color image data generating apparatus in the first aspect of the invention.

A sixth aspect of the invention provides a method of generating color image data associated with image process control data stipulating the image process conditions for the image data. The method in the sixth aspect of the invention comprises: generating color image data; acquiring image process control data including monochromatic output image process conditions including RGB channel mix rate stipulating the proportion of R, G, and B components in the RGB color image data for obtaining monochromatic images from color images; and associating and outputting the acquiring image process control data and the generated color image data.

The method in the sixth aspect of the invention may provide the same action and effects as the color image data generating apparatus in the second aspect of the invention. The method that generates color image data in the sixth aspect of the invention may also be realized in a variety of ways in the same manner as the color image data generating apparatus in the second aspect of the invention.

A seventh aspect of the invention provides a method of implementing an image process on image data. The image processing method in the seventh aspect of the invention comprises: acquiring color image data; acquiring image process control data that is associated with the color image data and that stipulates the image process conditions for the image data, wherein the image process control data includes monochromatic output image process conditions for outputting color image data in the form of monochromatic images; and converting the color image data to monochromatic image data using the acquired monochromatic output image process conditions.

The image processing method in the seventh aspect of the invention may provide the same action and effects as the image processing apparatus in the third aspect of the invention. The image processing method in the seventh aspect of the invention may also be realized in a variety of ways in the same manner as the image processing apparatus in the third aspect of the invention

An eighth aspect of the invention provides an image processing method of implementing an image process on image data. The image processing method in the eighth aspect of the invention comprises: acquiring color image data; acquiring photograph scene data that is associated with the color image data and relates to the photograph scene when the image data is generated; acquiring monochromatic output image process conditions, according to the acquired photograph scene, from storage module for storing a plurality of monochromatic output image process conditions correlated with photograph scenes; and converting the color image data to monochromatic image data using the acquired monochromatic output image process conditions.

The image processing method in the eighth aspect of the invention may provide the same action and effects as the image processing apparatus in the fourth aspect of the invention. The image processing method in the eighth aspect of the invention may also be realized in a variety of ways in the same manner as the image processing apparatus in the fourth aspect of the invention

The methods in the fifth through eighth aspects of the invention may also be realized in the form of programs, and computer-readable media on which such programs have been recorded.

### BRIEF DESCRIPTION OF THE DRAWINGS

FIG. 1 illustrates the schematic structure of an image processing system comprising a image data generating apparatus and image processing apparatus in an embodiment.

FIG. 2 illustrates the general structure of the image data generating apparatus in the embodiment.

FIG. 3 illustrates the general structure of the image processing apparatus in the embodiment.

FIG. 4 is a block diagram of the functional modules realized by the control circuit of the digital still camera in the embodiment.

FIG. 5 is a flow chart of the entire processing routine of the color image data generating process performed in the digital still camera in the embodiment.

FIG. 6 is a flow chart of the process routine in the process that generates the monochromatic output image processing conditions performed in the digital still camera in the embodiment.

FIG. 7 illustrates an example of statistical values for hue obtained by analysis of the color image data.

FIG. 8 illustrates an example of the correspondence between the maximum proportion hue and the determination threshold used to determine the properties of the color image data.

FIG. 9 illustrates an example of a table matching the maximum proportion hue and channel mix rate.

FIG. 10 illustrates an example of a table matching the photograph scene and channel mix rate.

FIG. 11 illustrates examples of parameters included in image process control data comprising monochromatic output image process conditions, which are generated or acquired by the digital still camera in the embodiment.

FIG. 12 schematically illustrates the data structure of the color image data generated by the digital still camera in the embodiment.

FIG. 13 is a block diagram of the functional modules realized by the control circuit of a color printer in the embodiment.

FIG. 14 is a flow chart of the process routine of the image process comprising a monochromatic image data conversion process performed in the color printer in the embodiment.

### DESCRIPTION OF THE PREFERRED EMBODIMENTS

The color image data generating apparatus, color image data generating method, image processing apparatus, and image processing method of the invention are described in the following embodiments with references to the drawings.

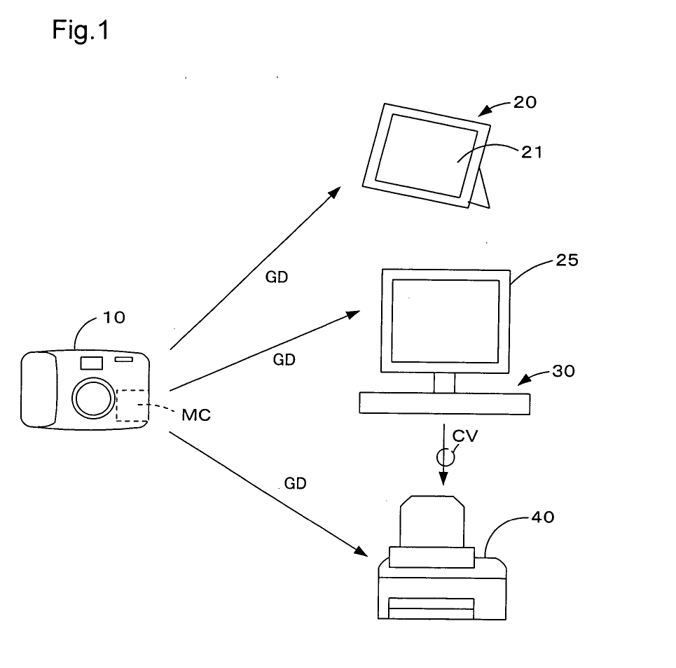

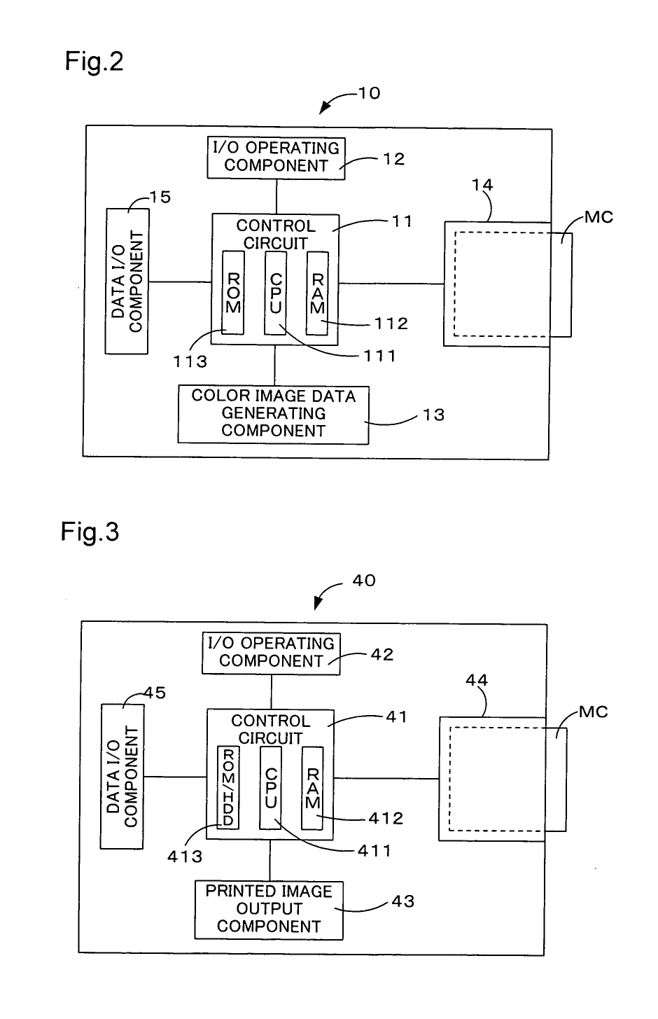

An embodiment of an image processing system including a color image data generating apparatus and image processing apparatus is described below with reference to FIGS. 1 through 3. FIG. 1 illustrates the general structure of the image processing system in this embodiment which includes a color image data generating apparatus and image processing apparatus. FIG. 2 illustrates the general structure of the color image data generating apparatus in the embodiment. FIG. 3 illustrates the general structure of the image processing apparatus in the embodiment.

The image processing system comprises a digital still camera 10 as the color image data generating apparatus, and a display 20, personal computer 30, and color printer 40 as the image processing apparatus for performing an image process on the image data GD comprising the color image data using the image process control data GI associated with the image data GD.

The digital still camera 10 is a camera that obtains (generates) digital image data by focusing light data on a digital device (photoelectric transformer elements known as CCD or photoelectric multipliers). As illustrated in FIG. 2, the digital still camera 10 includes a control circuit 11, I/O operating component 12, color image data generator 18, memory card slot 14, and data I/O component 15.

The control circuit 11 includes a central processing unit (CPU) 111 for running various computing processes such as the color image data generating process and analytical processes, random access memory (RAM) 112 for temporarily storing various types of data such as the generated color image data and computed results, and read-only memory (ROM) 113 for storing tables for the monochromatic image processing conditions, such as the RGB channel mix rate, and programs run by the CPU 111.

The I/O operating component 12 is an interface for receiving external input, and may be realized, for example, in the form of a keyboard, scrolling component, or touch panel.

The color image data generating component 13 comprises, for example, a CCD in which R, G, and B filters are disposed according to specific rules for each structural pixel, and generates digital color image data corresponding to the photographed subjects. More specifically, R component pixel data is directly obtained in pixels with R filters, while G and B component pixel data is generated by interpolation based on the surrounding pixel data. The generated color image data is stored in a memory card MC serving as the storage device. Examples of formats for storing color image data in digital still cameras 10 include the JPEG data format as an irreversible compression storage format, and the TIFF data format as a reversible compression storage format, but other storage formats which may be used include the RAW data format, GIF data format, and BMP data format.

The memory card slot 14 is a component for the installation of various memory cards. Reading and writing to the memory card installed in the memory card slot 14 are controlled by the control circuit 41.

The data I/O component 15 has terminals for connecting cable CV and the like, and a signal transforming process function, and is used for the exchange of image data with external devices.

The display device 20 functions as a photoelectric photograph frame, for example, having a display 21 for displaying images, and displays output images by stand-alone processing of the color image data by the same image processing as the image processing in the color printer 40 described below. The display device 20 obtains color image data through, for example, recording media, wireless communications such as IR communications or radiowave communications, or through cables, from a digital still camera 10 or server on a network (not shown). The display 21 is, for example, a liquid crystal display or organic EL display, and has the property of independent image output on each display panel.

The personal computer 30 is, for example, a general purpose type of computer, comprising a CPU, RAM, and hard disk, and executes image processes similar to the image processes in the color printer 40 described below. The personal computer 30 also comprises a memory card slot for the installation of a memory card MC, and I/O terminals to connect cables from the digital still camera 10 or the like.

The color printer 40 is capable of outputting color images. In this embodiment, it stands alone and outputs monochromatic images by running a monochromatic image process. As illustrated in FIG. 3, the color printer 40 comprises a control circuit 41, I/O operating component 42, printed image output component 43, memory card slot 44, and data I/O component 45.

The control circuit 41 comprises a central processing unit (CPU) 411 for running various computing processes such as image processing and analytical processes on color image data, random access memory (RAM) 412 for temporarily storing various types of data such as color image data which has undergone an image process and computer results, and a read-only memory (ROM) 413 for storing tables that show various parameters such as monochromatic image processing conditions corresponding to the photograph scene and programs that are run by the CPU 111.

The I/O operating component 42 is an interface which receives external input, and may be realized in the form of a key operator, scroll operator, touch panel type operator, or the like.

The printed image output component 43 is an ink jet type of printed image output component that forms images by forming dot patterns by spraying four colors of ink comprising cyan (C), magenta (M), yellow (Y), and black (K), for example, onto print media based on the print image data output from the control circuit 41. Alternatively, it is an electronic copier type of printed image output device that forms images by transferring and fixing color toner on print media. In addition to the four colors noted above, the colored ink may include light cyan (LC), light magenta (LM), blue, and red.

The memory card slot 44 is a component for the installation of various memory cards. Reading and writing to the memory card installed in the memory card slot 14 are controlled by the control circuit 41.

The data I/O component 45 has terminals for connecting cable CV and the like, and a signal transforming process function, and is used for the exchange of image data with external devices.

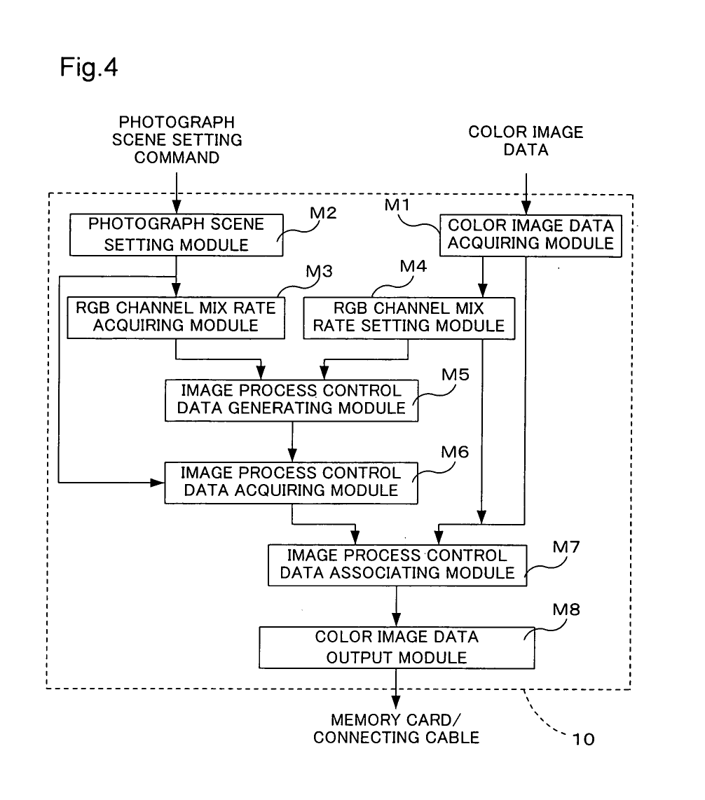

An outline of the modules realized by the control circuit 11 of the digital still camera 10 is given below with reference to FIG. 4. FIG. 4 is a block diagram of the functional modules realized by the control circuit 11 of the digital still camera 10 in this embodiment. The modules illustrated in FIG. 4 may be realized in terms of the CPU alone or the control circuit 11, and may be realized by either hardware or software.

The generated color image data is acquired by the control circuit 11 by means of the color image data acquiring module M1, and is sent to the RGB channel mix rate setting module M3 or the image process control data association module M7.

The photograph scene setting module M2 sets the photograph scene, such as portrait, landscape, or night time, according to the photograph scene setting command input through the I/O operating component 12. The RGB channel mix rate setting module M3 acquires monochromatic output image process conditions including the RGB channel mix rate from the storage device using the set photographic scene.

When no photograph scene setting command is input, monochromatic output image process conditions including the RGB channel mix rate are generated (set) by the RGB channel mix rate setting module M4. The RGB channel mix rate setting module M4 sets monochromatic output image processing conditions suitable for the acquired color image data using data such as hue which is obtained by analysis of the acquired color image data.

The image process control data generating module M5 generates image process control data using the monochromatic output image processing conditions which have been acquired or set, and the image process control data acquiring module M6 acquires the generated image process control data and forwards it to the image process control data associating module M7. The image process control data including the monochromatic output image processing conditions may be pre-stored in the storage device according to photographic scene. In such cases, image process control data acquiring module M6 acquires the image process control data according to the photograph scene.

The image process control data associating module M7 associates the acquiring image process control data with the color image data. The data is associated by generating association files storing data associating the color image data with the image process control data, wherein the image process control data is written in the header of the color image data. The color image data output module M8 outputs the color image data associated with the image process control data to the memory card or connecting cable.

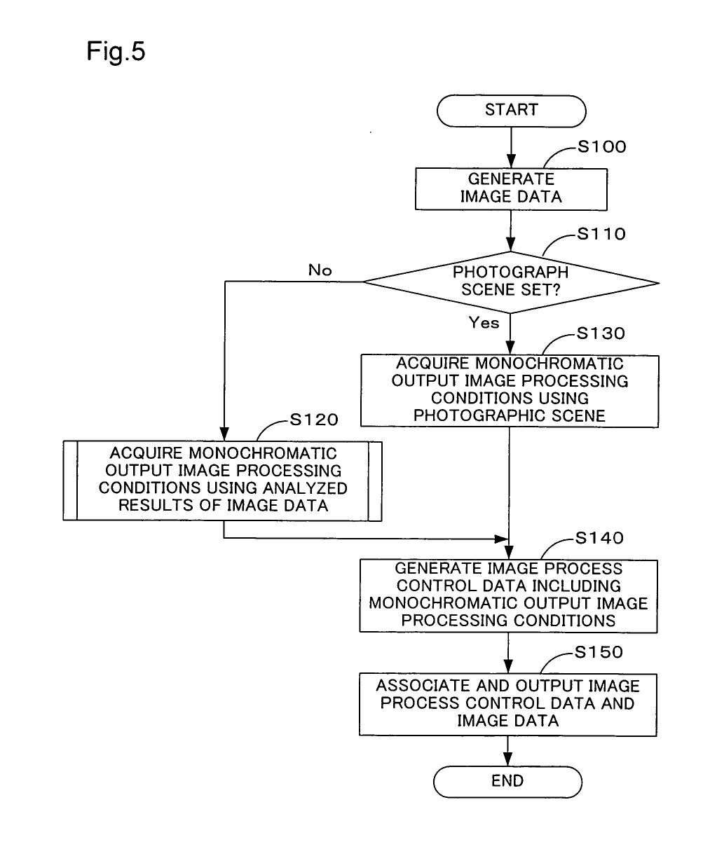

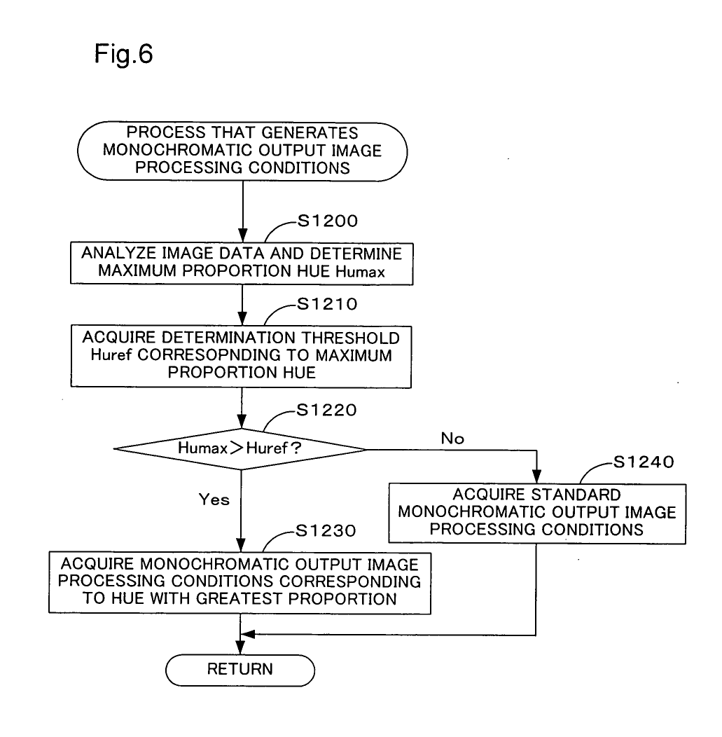

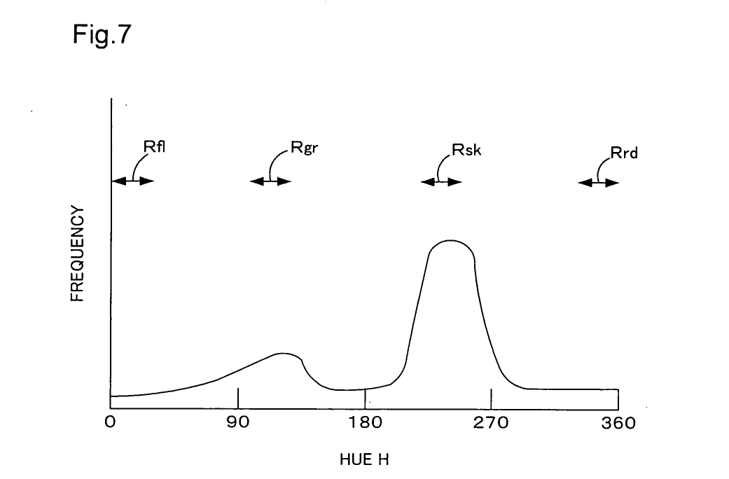

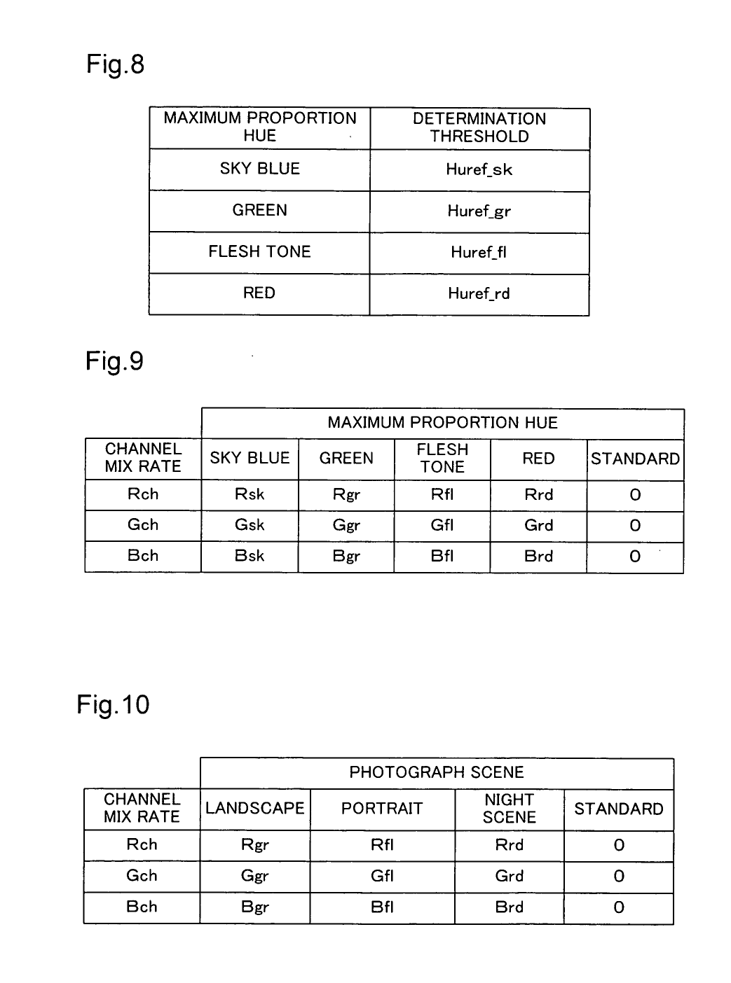

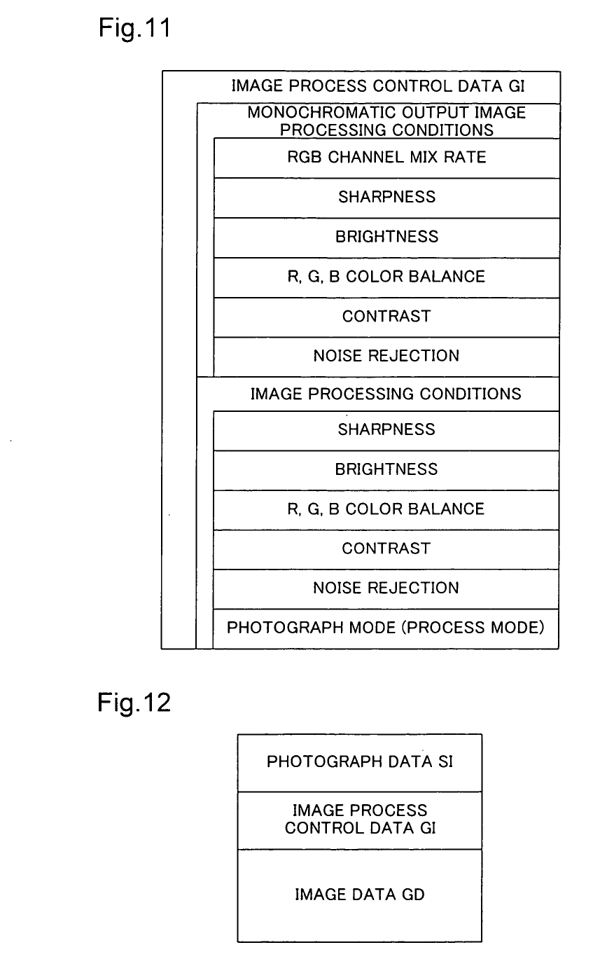

The color image data generating process performed in the digital still camera 10 as the color image data generating apparatus in this embodiment will be described with reference to FIGS. 5 through 12. 5 FIG. 5 is a flow chart of the entire processing routine of the color image data generating process performed in the digital still camera in the embodiment. FIG. 6 is a flow chart of the process routine in the process that generates the monochromatic output image processing conditions performed in the digital still camera in the embodiment. FIG. 7 illustrates an example of statistical values for hue obtained by analysis of the color image data. FIG. 8 illustrates an example of the correspondence between the maximum proportion hue and the determination threshold used to determine the properties of the color image data. FIG. 9 illustrates an example of a table matching the maximum proportion hue and channel mix rate. FIG. 10 illustrates an example of a table matching the photograph scene and channel mix rate. FIG. 11 illustrates examples of parameters included in image process control data comprising monochromatic output image process conditions, which are generated or acquired by the digital still camera in the embodiment. FIG. 12 schematically illustrates the data structure of the color image data generated by the digital still camera in the embodiment.

The process routine in FIG. 5 starts when the shutter button is depressed by the photographer, for example. When the shutter button is depressed, the color image data generating component 13 generated color image data GD such as RGB color image data via a photoelectric transformer element such as a CCD.

The CPU 111 determines whether or not the photograph scene has been set (Step S110). When it is determined that no photograph scene has been set (Step S110: No), monochromatic output image processing conditions are acquired using the analyzes results of the image data GD (Step S120).

The process that generates monochromatic output image processing conditions using the analyzed results of the image data GD are described with reference to FIG. 6. The CPU 111 converts the generated RGB color image data GD, for example, to HSV color image data, and produces a histogram such as that illustrated in FIG. 7, for the hues of the color image data. In this case, the HSV color space represents the color image data GD by means of hue H, saturation S, and brightness V. The hue H of the color image data GD may otherwise be obtained by converting the color image data GD to HSL color space. The following Equations (1) through (3) are used in the conversion of the RGB color image data GD to HSV color image data.

$$\begin{matrix}R = V max & Equation ( 1 ) \\ H = \frac{π}{3} ( \frac{G - B}{V max - V min} ) & \\ G = V max & Equation ( 2 ) \\ H = \frac{π}{3} ( 2 + \frac{B - R}{V max - V min} ) & \\ B = V max & Equation ( 3 ) \\ H = \frac{π}{3} ( 4 + \frac{R - G}{V max - V min} ) & \end{matrix}$$

Here, V max=max |R, G, B|, V min=min |R, G, B|. When V max=V min, the hue is indefinite (achromatic). When the hue H<0, 2π is added to the calculated hue H. As a result, the value range of the hue H is 0 to 2π, but in this embodiment, the hue H is expressed with a value range of 0 to 360.

In the histogram illustrated in FIG. 7, the hue range corresponding to flesh tones is R fl, the hue range corresponding to green is R gr, the hue range corresponding to sky blue is R sk, and the hue range corresponding to red is R rd. In the histogram illustrated in FIG. 7, the hue for sky blue is represented with high frequency, and it may be assumed that the generated color image data GD corresponds to a photograph based on the sky. For example, the hue angle of sky blue may be 218°, the hue angle of green may be 75°, the hue angle of red may be 0°, and the hue angle of flesh tones may be 27°.

The CPU 111 determines the proportion of the number of pixels representing a specific hue relative to the total of pixels, and determines a specific hue having the highest proportion as the maximum proportion Humax (Step S1200). That is, the proportion of the number of pixel data of a specific hue relative to the total number of pixel data forming the color image data GD is determined. Specifically, since the pixel data represents specific hues by means of R, G, and B components, the pixel data within the hue ranges are each calculated, the following Equation (4) is then used to calculate the proportion of hue ranges Hurate relative to the total number of pixel data, and the proportion of the hue Hurate with the greatest proportion is the maximum proportion Humax.

$$Hurate = \frac{\text{number of pixels of specific hue}}{\text{total number of pixels}} \qquad Equation ( 4 )$$

The CPU 111 obtains the determination threshold Huref corresponding to the hue with the highest proportion according to the correspondence system shown in FIG. 8 (Step S1210), and determines whether or not the maximum proportion Humax is greater than the determination threshold Huref (Step S1220). When the CPU 111 determines that the maximum proportion Humax is greater than the determination threshold Huref (Step S1220: Yes), the monochromatic output image processing conditions corresponding to the hue with the highest proportion are acquired (Step S1230), followed by a return to the flow chart in FIG. 6.

A detailed description will be given of the channel mix rate as an example of the monochromatic output image processing conditions. The CPU 111 acquires the channel mix rate (R ch, G ch, B ch) by referring to the table shown in FIG. 9, which is stored in ROM 113. Because sky blue, green, flesh tones, and red are used as the specific hues in this embodiment, a channel mix rate (R ch, G ch, B ch) as well as a sky blue channel mix rate (R sk, G sk, B sk), green channel mix rate (R gr, G gr, B gr), flesh tone channel mix rate (R fl, G fl, B fl), and red channel mix rate (R rd, G rd, B rd) are each prepared. The parameters related to the monochromatic output image processing conditions, such as sharpness, brightness, contrast, noise rejection, and color balance, may be modified as needed according to the hue with the highest proportion.

Alternatively, they may be modified depending on the proportion of the entire image occupied by the subject of revision (major photographed subject) instead of the table. When, for example, sky blue occupies a high proportion, a channel mix rate for realizing a red filter function should be prepared, and when flesh tones occupy a high proportion, a channel mix rate realizing a green filter function should be prepared.

Specifically, when the sky accounts for a high proportion of a landscape image, the channel mix rate may be determined by the following equation.
R ch=k·(S ky-ave−S ky [R])
G ch=k·(S ky-ave−S ky [G])
B ch=k·(S ky-ave−S ky [B])

Here, Sky-ave=(Sky [R]+Sky [G]+Sky [B])/3, and k is a coefficient.

That is, the channel mix rate should be calculated in such a way that the saturation in the hue has a lower brightness (is darker), based on the RGB levels of the enhanced color area (color area occupying high proportion of the image).

When the CPU 111 determines that the maximum proportion Humax is not greater than the determination threshold Huref (Step S1220: No), standard monochromatic output image processing conditions are acquired (Step S1240), followed by a return to the flow chart in FIG. 6.

The description will now be based on FIG. 5 again. When the CU 111 determines that a photograph scene has been set (Step S110: Yes), monochromatic output image processing conditions are acquired using the photograph scene (Step S130). A detailed description will be given of the channel mix rate as an example of the monochromatic output image processing conditions. The CPU 111 acquires the channel mix rate (R ch, G ch, B ch) corresponding to the set photograph scene by referring to the table shown in FIG. 10, which is stored in ROM 113. When a landscape, portrait, and night scene have been prepared as photograph scenes, the images will be based on green, flesh tones, and red. A landscape channel mix rate (R gr, G gr, B gr), portrait channel mix rate (R fl, G fl, B fl), and night scene channel mix rate (R rd, G rd, B rd) are therefore prepared. In this case, other parameters related to the monochromatic output image processing conditions, such as sharpness, brightness, contrast, noise rejection, and color balance, may be modified as needed according to the set photograph scene.

Monochromatic output image processing conditions including the channel mix rate may be acquired by analyzing the color image data GD along with the photograph scene. For example, when landscape has been set as the photograph scene, the photographed image will be based on the sky. In such cases, it sometimes will not be possible to obtain an attractive monochromatic output image when the monochromatic output image processing conditions are based on green. Particularly in cases where the photograph scene is set to landscape, the analyzes results of the generated color image data GD may serve as a basis for determining if the monochromatic image data is based on green or on sky blue.

When the CPU 111 acquires the monochromatic output image processing conditions, it generates image processing control data GI including the monochromatic output image processing conditions. The image process control data GI illustrated in FIG. 11 is generated, for example. The image process control data GI in this embodiment includes monochromatic output image processing conditions for obtaining attractive monochromatic output images form the color image data GD, and image processing conditions used when obtaining color output images from the color image data GD. The values of the previously described picture-related parameters are noted in the monochromatic output image processing conditions, and the values for the image quality-related parameters of sharpness, brightness, color balance, contrast, noise rejection, and photograph mode (process mode) are noted in the image processing conditions. The image processing conditions are data stipulating the image processing conditions of the image data in the image processing apparatus comprising the printer 40 and personal computer 30, and should be set for various combinations taking into consideration the image data generating properties of the imaging device and the image output properties of the image output device.

After the monochromatic output image processing conditions have been generated or set, the CPU ill executes a image adjusting process including, for example, gamma correction, RGB-YCbCr color conversion, and compression, on the color image data GD that has been generated (Step S150). This process allows the generated RGB color image data to be converted to color image data in the Jpeg format, for example. When the monochromatic output image processing conditions are generated or set by commands from the user, these image quality adjusting processes may be carried out along with the generation of the color image data GD in Step S100.

The CPU 111 associats the generated image process control data GI with the color image data GD and outputs it to (records it on) the memory card MC (Step S160), completing the process routine. The color image data GD output to the memory card MC has the data structure shown in FIG. 12, for example. That is, the image process control data GI is noted in the header of the color image data GD, so that the image process control data GI and color image data GD may be associated. In addition to the image process control data GI, the various photographic conditions when photographs are taken may also be noted as photograph data SI in the header of the color image data GD. In addition, the color image data GD and image process control data GI may be associated by means of separate association files associating the two. FIGS. 11 and 12 schematically illustrate data stored in memory, for example, to elucidate the data and data structure.

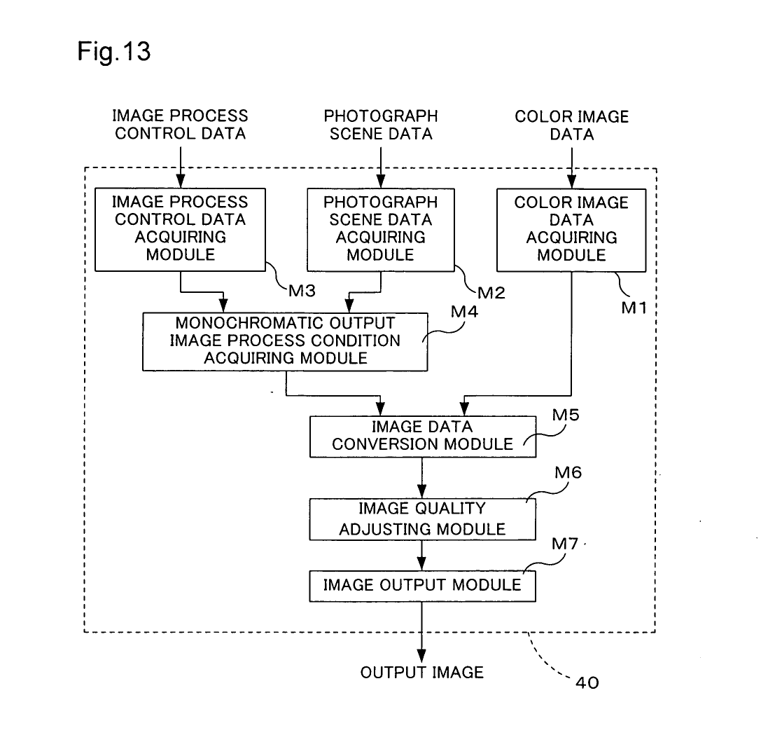

A general description will now be given of the modules realized by the control circuit 41 of the color printer with reference to FIG. 13. FIG. 13 is a block diagram of the functional modules realized by the control circuit 41 of the color printer 40 in this embodiment. The modules in FIG. 13 may be realized terms of the CPU alone or the control circuit 41, and may be realized by either hardware or software. The functional modules described below may similarly be realized by means of a display device 20 and personal computer 30.

In the color printer 40, the color image data GD is acquired by the control circuit 41 by means of the color image data acquiring module M1 and is sent to the image data conversion module M5.

The photograph scene comprising the photograph scene data included in the photograph data SI, such as the portrait, landscape, and night scene, is acquired by the photograph scene data acquiring module M2. The image processing control data GI is also acquired by the image process control data acquiring module M3.

The monochromatic output image process condition acquiring module M4 acquires the image process control data GI. When the monochromatic output image process conditions including the RGB channel mix rate may be retrieved and acquired, the acquired monochromatic output image process conditions are sent to the image data conversion module M5. When, on the other hand, the image process control data GI is not retrieved, and the monochromatic output image process conditions may not be acquired from the image process control data GI, the monochromatic output image process condition acquiring module M4 acquires the monochromatic output image process conditions corresponding to the photograph scene from the storage device and sends it to the image data conversion module M5. When the photograph scene data is not acquired, the monochromatic output image process condition acquiring module M4 uses data such as the hue obtained through analysis of the acquired color image data GD to set monochromatic output image process conditions suitable for the acquired color image data GD and sends it to the image data conversion module M5.

The image data conversion module M5 uses the RGB channel mix rate from among the acquired or set monochromatic output image processing conditions to convert the color image data GD to monochromatic image data and sends it to the image quality adjusting module M6. The image quality adjusting module M6 adjusts the image quality of the monochromatic image data obtained by the conversion according to other monochromatic output image processing conditions comprising sharpness and contrast, and sends the adjusted monochromatic image data to the image output module M7.

The image output module M7 outputs monochromatic output images using the monochromatic image data that has been received.

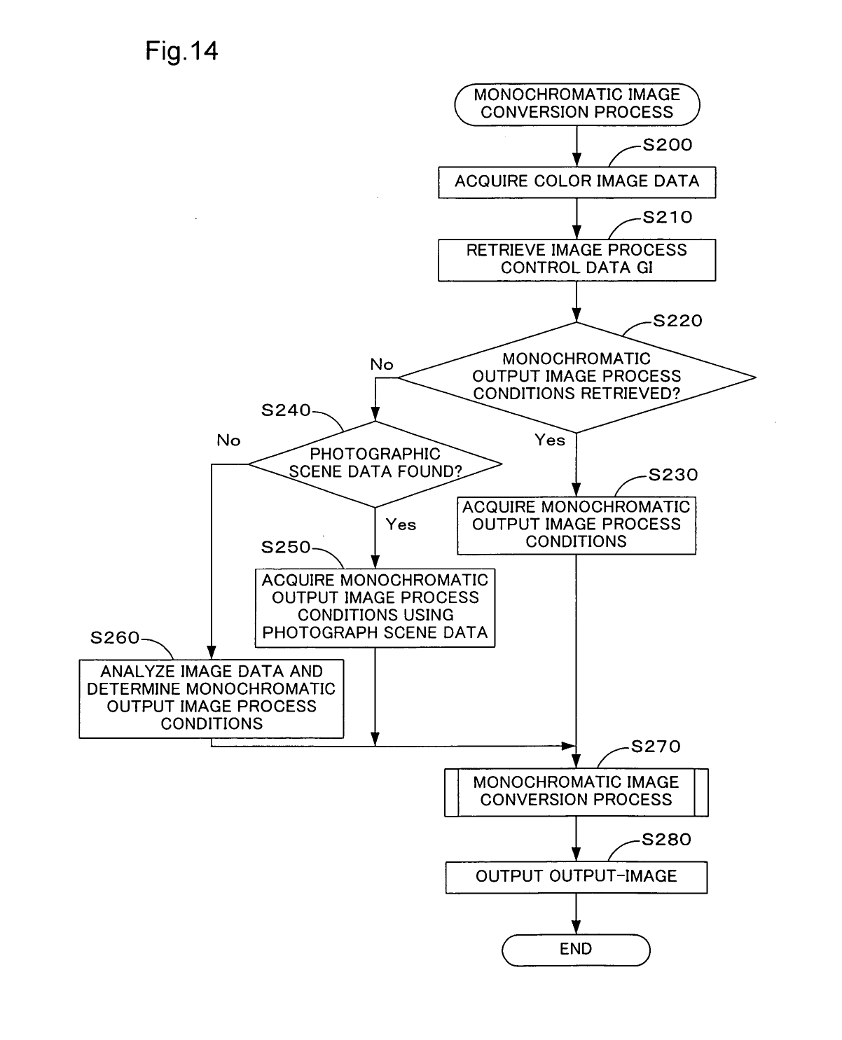

FIG. 14 will now be used as reference to describe the image process including the monochromatic image data conversion process performed in the color printer 40 serving as the image processing apparatus in this embodiment. FIG. 14 is a flow chart of the process routine of the image process comprising a monochromatic image data conversion process performed in the color printer in this embodiment.

The image process carried out in this embodiment starts when, for example, the monochromatic image output on the color printer 40 is selected and the memory card MC is inserted into the memory slot 44 of the color printer or when the digital still camera 10 is connected to the color printer 40 by a cable CV. Alternatively, it starts when the monochromatic image output on the color printer 40 is selected rather than the color image output after the memory card MC has been inserted into the memory slot 44 of the color printer 40 or the digital still camera 10 has been connected by a cable CV. That is, the user selects the output for either color images or monochromatic images.

When the image process is started, the control circuit 41 (CPU 411) acquires the selected color image data GD and temporarily stores it in RAM 412 (Step S200). Since the color image data GD generated in the digital still camera 10 is generally YCbCr data, the CPU 411 converts the YCbCr data to RGB data when the selected color image data GD is opened. The color image data GD may be selected, for example, on a digital still camera 10 connected with or without a line to the color printer 40, or it may be selected on the color printer 40 from the image data GD stored on the memory card MC. It may also be selected from a plurality of color image data GD stored on a server via a network.

The CPU 411 retrieves the image process control data GI associated with the selected color image data GD (Step S210), and retrieves the monochromatic output image processing conditions (Step S220). Specifically, the CPU 411 retrieves the header of the color image data GD or retrieves image process control data GI in a separate file format associated with the image data GD on the memory card MC or over a network, and determines whether or not the monochromatic output image processing conditions have been noted. When the monochromatic output image processing conditions is found (retrieved) in the image process control data GI (Step S220: Yes), the CPU 411 acquires the monochromatic output image processing conditions (Step S230). As illustrated in FIG. 11, the monochromatic output image processing conditions stipulate the RGB channel mix rate for monochromatic conversion of the color image data GD, and the other image quality-related parameters such as sharpness, contrast, brightness, and noise rejection for making the monochromatic image data more attractive.

When no monochromatic output image processing conditions is found (retrieved (Step S220: No), the CPU 411 retrieves the photograph scene data (Step S230). Specifically, the data is retrieved from image process control data GI or photograph data SI stored in the header of the color image data GD, or from image process control data GI or photograph data SI in a separate file format associated with the color image data GD.

When photograph scene data is retrieved (found) (Step S240: Yes), the CPU 411 acquires monochromatic output image processing conditions using the photograph scene data (Step S250). Specifically, the monochromatic output image processing conditions are acquired with reference to a table, such as that illustrated in FIG. 10, matching photograph scenes with channel mix rates or a table matching photograph scenes with other image quality-related parameters such as sharpness, contrast, brightness, and noise rejection. These tables are stored in a storage device such as ROM or an HDD 413.

When no photograph scene data is found (Step S240: No), the CPU 411 analyzes the acquired color image data GD to determine the monochromatic output image processing conditions (Step S260). Specifically, it is carried out in the same manner as described for the process to generate monochromatic output image processing conditions in the digital still camera 10.

When monochromatic output image processing conditions are acquired, the CPU 411 carries out the monochromatic image conversion process for converting the acquired color image data GD to monochromatic image data (Step S270). Specifically, the acquired channel mix rate is adapted to the following Equation (5) to convert the image data (R, G, B) in the RGB color image data GD to image data consisting only of luminance Y, converting the color image data GD to monochromatic image data.

$$Y = \frac{( 38 + Rch )}{128} * R + \frac{( 76 + Gch )}{128} * G + \\ \frac{( 14 + Bch )}{128} * B \qquad Equation ( 5 )$$

As a result, the image data of the RGB color image data GD is represented in the form of image data having only luminance Y, and is monochromatized. The CPU 411 furthermore adapts other monochromatic output image processing conditions to the monochromatized image data to adjust the image quality of the monochromatic image data. Examples of the adaptation of other monochromatic output image processing conditions are given below.

(1) Contrast Correction:

When landscape photographed: contrast increased When portrait photographed: contrast not increased or slightly lowered

(2) Sharpness Correction:

When landscape photographed: sharpness increased When portrait photographed: sharpness not increased or slightly lowered (softened)

(3) Color Balance Correction:

When adjusted to sepia tones: R:+25; G:0; B:−25

When adjusted to warm tones: R:+4; G:−1; B:−3

When adjusted to cool tones: R:−6; G:0; B:+6

These parameters may be adjusted to obtain image quality adjustments similar to those obtained with color image data. It is thus possible to make more attractive monochromatic images.

The CPU 411 generates monochromatic image data for output (for printing) using the adjusted monochromatic image data, and outputs the monochromatic image through a printed image output component 43, completing the process routine (Step S270).

As described above, a digital still camera 10 serving as the color image data generating apparatus in this embodiment may generate or acquire monochromatic output image processing conditions when color image data GD is converted to monochromatic image data according to the properties of the color image data GD that has been generated. It is thus possible to generate or set monochromatic output image processing conditions adapted to the various image quality properties of the color image data GD and the photograph conditions of the photograph scene. That is, it is possible to generate or set monochromatic output image processing conditions for obtaining monochromatic image data in which desired color areas are enhanced in the color image data generating apparatus.

Because the generated or set monochromatic output image processing conditions may also be associated with the generated color image data GD, the color image data GD may be easily and rapidly converted to monochromatic image data.

The color printer 40 used as the image processing apparatus in this embodiment may convert the color image data GD to monochromatic image data using monochromatic output image processing conditions associated with the color image data GD. It is thus possible to output more attractive monochromatic images in which desired color areas have been enhanced with a color image data generating apparatus such as a digital still camera 10 using the color image data GD.

When no monochromatic output image processing conditions are associated with the color image data GD, monochromatic output image processing conditions may be acquired from photograph scene data associated with the color image data, allowing the color image data to be converted to monochromatic image data. Because the photograph scene data is associated with an abundance of color image data, more color image data may be converted to monochromatic data using the monochromatic output image processing conditions to output more attractive monochromatic images. When not photograph scene data is associated with the color image data GD, monochromatic output image processing conditions may be generated through analysis of the color image data GD, ensuring that attractive monochromatic images may be output using the color image data GD.

### Other Embodiments

In the above embodiments, a digital still camera 10 was used as the color image data generating apparatus, but other imaging devices such as scanners may also be used. In such cases, the same effects as in the above embodiment may be obtained.

The monochromatic conversion of color images was described in the above embodiments using RGB color space, but color images may be converted to monochromatic images by modifying the channel mix rate in other color spaces such as HSB, Lab, Luy, and YCbCr color spaces.

A color printer 40 was used as the image processing apparatus in the above embodiment, but a display device 20 and personal computer 30 may also be used. In such cases, the same effects will be obtained as in the above embodiment. Monochromatic output image processing conditions suitable for screen display may be generated or set for when the final output form of the monochromatic data is a screen display.

The color image data generating process carried out in the digital still camera 10 in the above embodiment may be implemented in the form of image processing applications (programs) without the hardware structure. The image process carried out in the color printer 40 may also be implemented in the form of a printer driver or image processing application (program) without the hardware structure.

The color image data generating process and image process in the above embodiment may be carried out by software such as a computer program, but they may also be carried out using an image process hardware circuit equipped with a logical circuit for implementing the above processes (steps). In such cases, the load on the CPU 111 and 411 may be alleviated, allowing the process to be completed more rapidly. The image process hardware circuit may be implemented as a circuit for the digital still camera 10, display device 20, and color printer 40, for example, and as an add-on card for the personal computer 30.

Color image data generating apparatuss, image processing apparatuss, color image data generating methods, image processing methods, color image data generating programs, and image processing methods of the invention have been described based on the above embodiments, but these embodiments of the invention were intended to facilitate an understanding of the invention and do not limit the invention. The invention may be modified and improved without departing from the spirit of the invention, and such equivalents are included in the invention.

1. A color image data generating apparatus that generates color image data, the color image data generating apparatus comprising:
color image data generating module that generates color image data;
image process control data acquiring module that acquires image process control data that stipulates the image process conditions for the generated color image data, wherein the image process control data includes monochromatic output image process conditions for outputting the generated color image data in the form of monochromatic images; and
color image data output module that associates and outputs the acquiring image process control data and the generated color image data.

2. A color image data generating apparatus according to claim 1, wherein the monochromatic output image process conditions include RGB channel mix rate stipulating the proportion of R, G, and B components in the RGB color image data for obtaining monochromatic image from color image.

3. A color image data generating apparatus according to claim 2 further comprising:
RGB channel mix rate setting module that sets the RGB channel mix rate by analyzing the color image data; and
image process control data generating module that generates image process control data including the set RGB channel mix rate, wherein the image process control data acquiring module acquires the generated image process control data.

4. A color image data generating apparatus according to claim 2 further comprising:
storage module for storing a plurality of RGB channel mix rates according to the conditions under which the color image data is generated;
RGB channel mix rate acquiring module that acquires RGB channel mix rates from the storage module according to the conditions under which the data is generated; and
image process control data generating module that generates image process control data including the acquired RGB channel mix rate, wherein
the image process control data acquiring module acquires the generated image process control data.

5. A color image data generating apparatus according to claim 2, wherein
the monochromatic output image process conditions further include suitable conditions for brightness, contrast, color balance, noise rejection, and sharpness in order to obtain monochromatic image from color image.

6. A imaging device that generates color image data, the imaging device comprising:
color image data generating module that generates color image data;
image process control data acquiring module that acquires image process control data that stipulates the image process conditions for the generated color image data, wherein the image process control data includes RGB channel mix rate stipulating the proportion of R, G, and B components in the RGB color image data for obtaining monochromatic image from color image; and
image data output module that associates and outputs the acquired image process control data and the generated color image data.

7. A imaging device according to claim 6 further comprising:
photograph scene setting module that sets the photograph scene when taking photographs;
RGB channel mix rate setting module that sets the RGB channel mix rate using the photographic scene; and
image process control data generating module that generates image process control data including the set RGB channel mix rate, wherein
the image process control data acquiring module acquires the generated image process control data.

8. A imaging device according to claim 6 further comprising:
photograph scene setting module that sets the photograph scene when taking photographs;
storage module for storing a plurality of RGB channel mix rates according to the photograph scene;
RGB channel mix rate acquiring module that acquires RGB channel mix rates from the storage module according to the set photographic scene; and
image process control data generating module that generates image process control data including the acquired RGB channel mix rate, wherein
the image process control data acquiring module acquires the generated image process control data.

9. A imaging device according to claim 6, wherein
the image process control data further includes suitable conditions for brightness, contrast, color balance, noise rejection, and sharpness in order to obtain monochromatic images from color images.

10. An image processing apparatus for implementing an image process on image data, the image processing apparatus comprising:
color image data acquiring module that acquires color image data;
image process control data acquiring module that acquires image process control data associated with the color image data and stipulating the image process conditions for the image data, wherein the image process control data includes monochromatic output image process conditions for outputting color image data in the form of monochromatic images; and
image data conversion module that converts the color image data to monochromatic image data using the acquired monochromatic output image process conditions.

11. An image processing apparatus according to claim 10 further comprising:
image quality adjusting module that adjusts the image quality of the monochromatic image data according to the image process conditions stipulated by the acquiring image process control data.

12. An image processing apparatus according to claim 10, wherein the monochromatic output image process conditions include the RGB channel mix rate stipulating the proportion of R, G, and B components in the RGB color image data for obtaining monochromatic images from color images.

13. An image processing apparatus for implementing an image process on image data, the image processing apparatus comprising:
image data acquiring module that acquires color image data;
photographic scene data acquiring module that acquires photograph scene data that is associated with the color image data and relates to the photograph scene when the image data is generated;
storage module for storing a plurality of monochromatic output image process conditions correlated with photograph scenes;
monochromatic output image process condition acquiring module that acquires monochromatic output image process conditions from the storage module according to the acquired photograph scene; and
image data conversion module that converts the color image data to monochromatic image data using the acquired monochromatic output image process conditions.

14. An image processing apparatus according to claim 13, wherein the monochromatic output image process conditions include the RGB channel mix rate stipulating the proportion of R, G, and B components in the RGB color image data for obtaining monochromatic images from color images.

15. An image processing apparatus according to claim 10, wherein the monochromatic output image process conditions further include suitable conditions for brightness, contrast, color balance, noise rejection, and sharpness in order to obtain monochromatic images from color images.

16. A method of generating color image data associated with image process control data stipulating the image process conditions for image data, the method comprising:
generating color image data;
acquiring image process control data including monochromatic output image process conditions for outputting the generated color image data in the form of monochromatic images; and
associating and outputting the acquiring image process control data and the generated color image data.

17. A method of generating color image data associated with image process control data stipulating the image process conditions for image data, the method comprising:
generating color image data;
acquiring image process control data including monochromatic output image process conditions, wherein the monochromatic output image process conditions includes the RGB channel mix rate stipulating the proportion of R, G, and B components in the RGB color image data for obtaining monochromatic images from color images; and
associating and outputting the acquiring image process control data and the generated color image data.

18. An image processing method of implementing an image process on image data, the method comprising:
acquiring color image data;
acquiring image process control data that is associated with the color image data and that stipulates the image process conditions for the image data, wherein the image process control data includes monochromatic output image process conditions for outputting color image data in the form of monochromatic images; and
converting the color image data to monochromatic image data using the acquired monochromatic output image process conditions.

19. An image processing method of implementing an image process on image data, the image processing method comprising:
acquiring color image data;
acquiring photograph scene data that is associated with the color image data and relates to the photograph scene when the image data is generated;
acquiring monochromatic output image process conditions, according to the acquired photograph scene, from storage module for storing a plurality of monochromatic output image process conditions correlated with photograph scenes; and
converting the color image data to monochromatic image data using the acquired monochromatic output image process conditions.
